(19) United States
(12) Patent Application Publication
(10) Pub. No.: US 2024/0204149 A1
(43) Pub. Date: Jun. 20, 2024

(54) DISPLAY DEVICE COMPRISING DISPLAY MODULE, AND METHOD FOR MANUFACTURING SAME

(71) Applicant: Samsung Electronics Co., Ltd., Suwon-si (KR)

(72) Inventors: Tackmo Lee, Suwon-si (KR); Gunwoo Kim, Suwon-si (KR); Seonghwan Shin, Suwon-si (KR); Gyun Heo, Suwon-si (KR); Soonmin Hong, Suwon-si (KR)

(73) Assignee: Samsung Electronics Co., Ltd., Suwon-si (KR)

(21) Appl. No.: 18/593,207

(22) Filed: Mar. 1, 2024

Related U.S. Application Data
(63) Continuation of application No. PCT/KR2022/014931, filed on Oct. 5, 2022.

(30) Foreign Application Priority Data
Nov. 24, 2021 (KR) 10-2021-0163502
Jan. 14, 2022 (KR) 10-2022-0006013

(51) Int. Cl. H01L 33/48; H01L 25/075; H01L 25/16; H01L 27/15; H01L 33/62

(52) U.S. Cl. CPC H01L 33/486; H01L 25/0753; H01L 25/167; H01L 27/156; H01L 33/62; H01L 2933/0066

(57) ABSTRACT

A display module includes a substrate including a mounting surface on which a plurality of inorganic light-emitting devices are mounted, a side surface, and a rear surface opposite to the mounting surface; a front cover covering the mounting surface and extending to an outer area from the mounting surface; a metal plate positioned on the rear surface of the substrate; a side molding covering the side surface and positioned below the outer area from the mounting surface; and a grounding member grounded to the metal plate and adhered to a lower surface of the side molding, where the side molding is injection-molded on the side surface of the substrate and is in contact with the side surface.

### CROSS-REFERENCE TO RELATED APPLICATIONS

This application is a continuation of International Application No. PCT/KR2022/014931, filed on Oct. 5, 2022, in the Korean Intellectual Property Receiving Office, which is based on and claims priority to Korean Patent Applications No. 10-2022-0006013, filed on Jan. 14, 2022 and No. 10-2021-0163502, filed on Nov. 24, 2021, in the Korean Intellectual Property Office, the disclosures of which are incorporated by reference herein in their entireties.

### BACKGROUND

### 1. Field

The present disclosure relates to a display device of displaying images by combining modules in which self-emissive inorganic light-emitting devices are mounted on substrates.

### 2. Description of Related Art

A display device is a kind of output device for visually displaying images and data information, such as characters, figures, etc.

Generally, as a display device, a liquid crystal panel requiring a backlight or an organic light-emitting diode (OLED) panel configured with a film of an organic compound that itself emits light in response to current has been widely used. However, the liquid crystal panel has a slow response time and high power consumption, and requires a backlight because itself cannot emit light. Accordingly, it is difficult to compactify the liquid crystal panel. Also, the OLED panel does not require a backlight and can achieve a small thickness because itself can emit light. However, the OLED panel is vulnerable to a burn-in phenomenon in which, when the same screen is displayed for a long time and then changes to another screen, a specific area of the previous screen remains as it is due to the short lifespan of the sub pixels. For these reasons, as a new panel that will substitute these, a micro light-emitting diode (referred to as a micro LED or a μLED) panel that uses inorganic light-emitting devices mounted on substrates as pixels is being studied.

The micro light-emitting diode panel (hereinafter, referred to as a micro LED panel), which is a flat display panel, is configured with a plurality of inorganic LEDs each having a size of 100 micrometers or less.

The micro LED panel does not cause the burn-in phenomenon of OLEDs as inorganic light-emitting devices that are self-emissive devices, while having excellent brightness, resolution, consumption power, and durability.

The micro LED panel provides better contrast, response time, and energy efficiency than the LCD panel requiring the backlight. Micro LEDs which are inorganic light-emitting devices have higher brightness, higher light-emitting efficiency, and a longer lifespan than OLEDs although both the OLEDs and micro LEDs have high energy efficiency.

Also, display modules can be manufactured in unit of substrates by arranging LEDs in unit of pixels on circuit boards, and accordingly, micro LED panels can be manufactured with various resolutions and screen sizes according to consumers' orders.

### SUMMARY

Provided is a display device and a manufacturing method thereof, and provides a technical feature of securing reliability against Electrostatic Discharge (ESD) and rigidity against external forces with respect to a substrate of a display module suitable for enlargement in the display module and a display device including the same.

Additional aspects will be set forth in part in the description which follows and, in part, will be apparent from the description, or may be learned by practice of the presented embodiments.

According to an aspect of an embodiment, a display module may include a substrate including a mounting surface on which a plurality of inorganic light-emitting devices are mounted, a side surface, and a rear surface opposite to the mounting surface; a front cover covering the mounting surface and extending to an outer area from the mounting surface; a metal plate positioned on the rear surface of the substrate; a side molding covering the side surface and positioned below the outer area from the mounting surface; and a grounding member grounded to the metal plate and adhered to a lower surface of the side molding, where the side molding is injection-molded on the side surface of the substrate and is in contact with the side surface.

A side end of the front cover positioned in the outer area from the mounting surface, and a side end of the side molding may be aligned in a direction which the mounting surface faces.

The display module may include a Thin Film Transistor (TFT) layer formed on the mounting surface, and an anisotropic conductive layer positioned on an upper surface of the TFT layer and configured to electrically connect the TFT layer to the plurality of inorganic light-emitting devices, where the anisotropic conductive layer extends to the outer area from the mounting surface.

A side end of the front cover positioned in the outer area from the mounting surface, and a side end of the anisotropic conductive layer positioned in the outer area from the mounting surface may be aligned in a direction which the mounting surface faces.

The side end of the front cover, the side end of the anisotropic conductive layer, and a side end of the side molding may be aligned in the direction which the mounting surface faces.

The side molding may include a chamfer portion positioned between the lower surface of the side molding and a side end of the side molding, where the grounding member extends from the metal plate and is in contact with the lower surface of the side molding and the chamfer portion of the side molding.

The grounding member may be positioned at a more inner location than the side end of the side molding in a direction that is orthogonal to a direction which the mounting surface faces.

According to an aspect of an embodiment, a display device including a display module array in which a plurality of display modules are arranged horizontally in a matrix form of M*N, where each of the plurality of display modules may include a substrate including a mounting surface on which a plurality of inorganic light-emitting devices are mounted, a side surface, and a rear surface opposite to the mounting surface; a front cover covering the mounting surface and extending to an outer area from the mounting surface; a metal plate mounted on the rear surface of the substrate; a side molding covering the side surface and positioned below the outer area from the mounting surface; and a grounding member being grounded to the metal plate and adhered to a lower surface of the side molding, where the side molding is injection-molded on the side surface of the substrate and is in contact with the side surface.

A side end of the front cover positioned in the outer area from the mounting surface, and a side end of the side molding may be aligned in a direction which the mounting surface faces.

The display device may further include a thin film transistor (TFT) layer formed on the mounting surface, and an anisotropic conductive layer positioned on an upper surface of the TFT layer and configured to electrically connect the TFT layer to the plurality of inorganic light-emitting devices, where the anisotropic conductive layer extends to the outer area from the mounting surface.

The side end of the front cover positioned in the outer area from the mounting surface, and a side end of the anisotropic conductive layer positioned in the outer area from the mounting surface may be aligned in the direction which the mounting surface faces.

The side molding may include a chamfer portion positioned between the lower surface of the side molding and a side end of the side molding, where the grounding member extends from the metal plate and is in contact with the lower surface of the side molding and the chamfer portion of the side molding.

The grounding member may be positioned at a more inner location than the side end of the side molding in a direction that is orthogonal to the direction which the mounting surface faces.

According to an aspect of an embodiment, a method of manufacturing a display module may include providing a substrate including a mounting surface on which a Thin Film Transistor (TFT) layer is formed, a side surface, and a rear surface opposite to the mounting surface, where a wire is formed on the substrate; injection-molding a side molding on the side surface of the substrate; adhering an anisotropic conductive film onto the TFT layer; mounting a plurality of inorganic light-emitting devices on the mounting surface; adhering a front cover onto the mounting surface, the front cover extending to an outer area from the mounting surface; and cutting the front cover, the anisotropic conductive film, and the side molding simultaneously in a direction which the mounting surface faces.

The method may further include providing a metal plate in contact with the rear surface of the substrate.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 shows a display device, according to an embodiment of the disclosure;

FIG. 2 is an exploded view showing main components of the display device of FIG. 1, according to an embodiment of the disclosure;

FIG. 3 is an enlarged cross-sectional view showing some components of a display module shown in FIG. 1, according to an embodiment of the disclosure;

FIG. 4 is a rear perspective view of a display module of the display device shown in FIG. 1, according to an embodiment of the disclosure;

FIG. 5 is a perspective view showing some components of a display module shown in FIG. 1, according to an embodiment of the disclosure;

FIG. 6 is a cross-sectional view showing some components of the display device of FIG. 1, taken in a second direction, according to an embodiment of the disclosure;

FIG. 7 is an enlarged cross-sectional view of some components shown in FIG. 6, according to an embodiment of the disclosure;

FIG. 8 is a cross-sectional view showing some components of the display device of FIG. 1, taken in a third direction, according to an embodiment of the disclosure;

FIG. 9 is an enlarged cross-sectional view of some components shown in FIG. 8, according to an embodiment of the disclosure;

FIG. 10 shows a process of manufacturing a display device according to an embodiment of the disclosure, according to an embodiment of the disclosure;

FIG. 11 shows a process of manufacturing the display device after FIG. 10, according to an embodiment of the disclosure;

FIG. 12 shows a process of manufacturing the display device after FIG. 11, according to an embodiment of the disclosure;

FIG. 13 shows a process of manufacturing the display device after FIG. 12, according to an embodiment of the disclosure;

FIG. 14 shows a process of manufacturing the display device after FIG. 13, according to an embodiment of the disclosure;

FIG. 15 shows a process of manufacturing the display device after FIG. 14, according to an embodiment of the disclosure;

FIG. 16 shows a process of manufacturing the display device after FIG. 15, according to an embodiment of the disclosure; and

FIG. 17 shows a process of manufacturing the display device after FIG. 16 according to the disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms. It is to be understood that singular forms include plural referents unless the context clearly dictates otherwise. The terms including technical or scientific terms used in the disclosure may have the same meanings as generally understood by those skilled in the art.

An expression used in the singular encompasses the expression of the plural, unless it has a clearly different meaning in the context. In the drawings, for clear descriptions, the shapes or sizes of components are more or less exaggeratedly shown.

It will be understood that when the terms “includes,” “comprises,” “including,” and/or “comprising,” when used in this specification, specify the presence of stated features, figures, steps, operations, components, members, or combinations thereof, but do not preclude the presence or addition of one or more other features, figures, steps, operations, components, members, or combinations thereof.

Also, in this specification, the meaning of ‘identical’ may include similar in attribute or similar within a certain range. Also, the term ‘identical’ means ‘substantially identical’. The meaning of ‘substantially identical’ needs to be understood that a value falling within the margin of error in manufacturing or a value corresponding to a difference within a meaningless range with respect to a reference value is included in the range of ‘identical’.

Hereinafter, an embodiment of the disclosure will be described in detail with reference to the accompanying drawings.

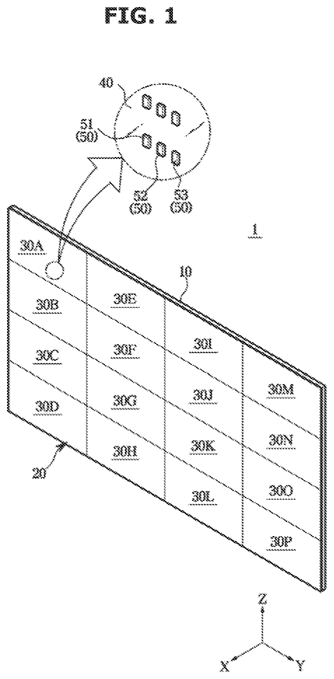

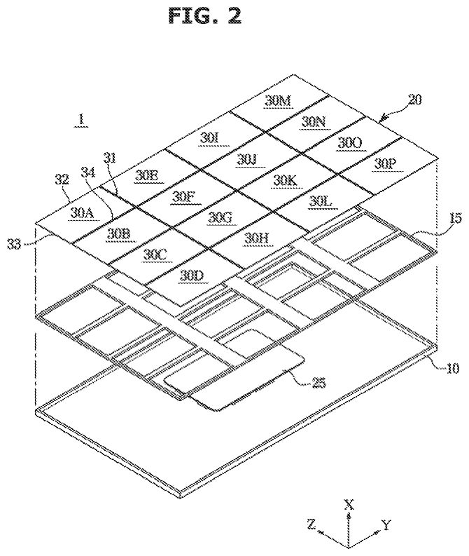

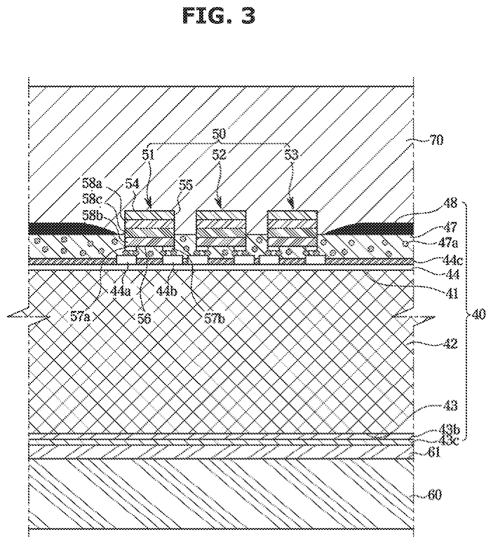

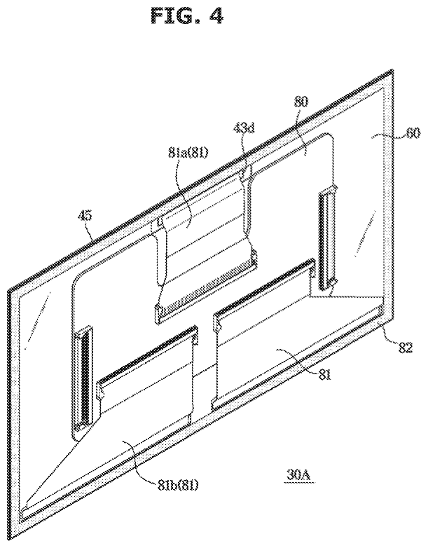

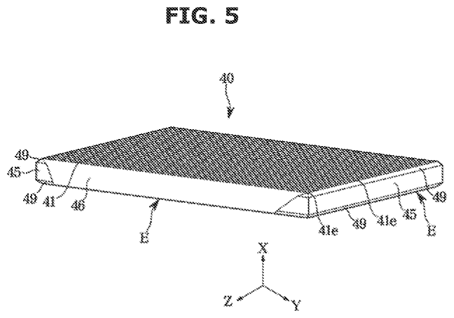

FIG. 1 shows a display device according to an embodiment of the disclosure. FIG. 2 is an exploded view showing main components of the display device of FIG. 1, FIG. 3 is an enlarged cross-sectional view showing some components of a display module shown in FIG. 1, FIG. 4 is a rear perspective view of a display module of the display device shown in FIG. 1, and FIG. 5 is a perspective view showing some components of a display module shown in FIG. 1.

Some components of a display device 1, including a plurality of inorganic light-emitting devices 50, shown in the drawings may be micro-scale components each having a size of several micrometers (μm) to hundreds of micrometers (μm), and for convenience of descriptions, some components (the plurality of inorganic light emitting devices 50, a black matrix 48, etc.) are exaggerated in scale.

The display device 1 may be a device for displaying information and data as characters, figures, graphs, images, etc., and the display device 1 may be a television (TV), a personal computer (PC), a mobile device, a digital signage, etc.

According to an embodiment of the disclosure, as shown in FIGS. 1 and 2, the display device 1 may include a display panel 20 for displaying an image, a power supply device for supplying power to the display panel 20, a main board 25 for controlling overall operations of the display panel 20, a frame 15 supporting the display panel 20, and a rear cover 10 covering a rear surface of the frame 15.

The display panel 20 may include a plurality of display modules 30A to 30P, a driving board for driving the individual display modules 30A to 30P, and a timing controller (TOCN) board for generating timing signals required for respectively controlling the display modules 30A to 30P.

The rear cover 10 may support the display panel 20. The rear cover 10 may be installed on a floor through a stand, or mounted on a wall through a hanger, etc.

The plurality of display modules 30A to 30P may be arranged in up, down, left, and right directions to be adjacent to each other. The plurality of display modules 30A to 30P may be arranged in a form of a M*N matrix. In the current embodiment, 16 display modules 30A to 30P may be arranged in a form of a 4*4 matrix. However, a number and arrangement of the plurality of display modules 30A to 30P are not limited.

The plurality of display modules 30A to 30P may be mounted on the frame 15. The plurality of display modules 30A to 30P may be mounted on the frame 15 by various known methods, such as a magnetic force generated by a magnet or a mechanical insert structure. A rear side of the frame 15 may be coupled with the rear cover 10, and the rear cover 10 may form a rear outer appearance of the display device 1.

The rear cover 10 may include a metal material. Accordingly, heat generated from the plurality of display modules 30A to 30P and the frame 15 may be easily transferred to the rear cover 10, which raises heat dissipation efficiency of the display apparatus 1.

As such, the display device 1 according to an embodiment of the disclosure may implement a large screen by tiling the plurality of display modules 30A to 30P.

Each of the plurality of display modules 30A to 30P may be applied to a display device. That is, the display modules 30A to 30P may be, in unit of a piece, installed in and applied to a wearable device, a portable device, a handheld device, various electronic products, or electronic parts requiring a display, Also, the display modules 30A to 30P may be applied to a display device, such as a monitor for PC, a high-resolution TV, a signage, an electronic display, etc., by being assembled and arranged in a matrix type, as in the embodiment of the disclosure.

The plurality of display modules 30A to 30P may have the same configuration. Accordingly, the following description about a display module may be applied in the same way to all the other display modules.

Hereinafter, a first display module 30A of the plurality of display modules 30A to 30P will be described because the plurality of display modules 30A to 30P have the same configuration.

That is, to avoid duplicate descriptions, as components of the plurality of display modules 30A to 30P, a display module 30, a substrate 40, and a front cover 70 will be representatively described.

Also, the first display module 30A of the plurality of display modules 30A to 30P and a second display module 30E being adjacent to the first display module 30A in a second direction Y or a third display module 30B being adjacent to the first display module 30A in a third direction Z will be described as necessary.

The first display module 30A of the plurality of display modules 30A to 30P may be formed, for example, in a quadrangle type. The first display module 30A may be formed in a rectangle type or a square type.

Accordingly, the first display module 30A may include edges 31, 32, 33, and 34 located in upper, lower, left, and right directions with respect to a first direction X which is a front direction.

As shown in FIG. 3, each of the plurality of display modules 30A to 30P may include the substrate 40, and the plurality of inorganic light-emitting devices 50 mounted on the substrate 40. The plurality of inorganic light-emitting devices 50 may be mounted on a mounting surface 41 of the substrate 40 toward the first direction X. In FIG. 3, for convenience of descriptions, a thickness in a first direction X of the substrate 40 is exaggerated.

The substrate 40 may be formed in a quadrangle type. As described above, because each of the plurality of display modules 30A to 30P is formed in a quadrangle type, the substrate 40 may also be formed in a quadrangle type correspondingly.

The substrate 40 may be formed in a quadrangle type or a square type.

Accordingly, in the example of the first display module 30A, the substrate 40 may include four edges E corresponding to the edges 31, 32, 33, and 34 of the first display module 30A, formed in the upper, lower, left, and right directions with respect to the first direction X which is the front direction (see FIG. 5).

The substrate 40 may include a substrate body 42, the mounting surface 41 forming one surface of the substrate body 42, a rear surface 43 forming another surface of the substrate body 42 and being opposite to the mounting surface 41, and a side surface 45 positioned between the mounting surface 41 and the rear surface 43.

The side surface 45 may form side ends of the substrate 40 in the second direction Y and the third direction Z that are orthogonal to the first direction X.

The substrate 40 may include a chamfer portion 49 formed between the mounting surface 41 and the side surface 45 and between the rear surface 43 and the side surface 45.

The chamfer portion 49 may prevent, upon an arrangement of the plurality of display modules 30A to 30P, each substrate from colliding with another one(s) and being damaged.

The edges E of the substrate 40 may include the side surface 45 and the chamfer portion 49.

The substrate 40 may include a thin film transistor (TFT) layer 44 formed on the substrate body 42 to drive the inorganic light-emitting devices 50. The substrate body 42 may include a glass substrate. That is, the substrate 40 may include a chip on glass (COG) type substrate. On the substrate 40, a first pad electrode 44a and a second pad electrode 44b may be formed to electrically connect the inorganic light-emitting devices 50 to the TFT layer 44.

TFTs configuring the TFT layer 44 are not limited to specific structures or types, and may be implemented as various embodiments. That is, TFTs of the TFT layer 44 according to an embodiment of the disclosure may be implemented as low temperature poly silicon (LTPS) TFTs, oxide TFTs, Si (poly silicon or a-silicon) TFTs, organic TFTs, or graphene TFTs.

Also, the TFT layer 44 may be replaced with a complementary metal-oxide semiconductor (CMOS) type, n-type MOSFT, or p-type MOSFET transistor, in a case in which the substrate body 42 of the substrate 40 is a silicon wafer.

The plurality of inorganic light-emitting devices 50 may be formed of an inorganic material, and each of the inorganic light-emitting devices 50 may have sizes of several micrometers (μm) to hundreds of micrometers (μm) in width, length, and height. A micro inorganic light-emitting device may have a shorter side length of 100 μm or less in width, length, and height. That is, the inorganic light-emitting devices 50 may be picked up from a sapphire or silicon wafer and then directly transferred onto the substrate 40. The plurality of inorganic light-emitting devices 50 may be picked up and conveyed through an electrostatic method using an electrostatic head or a stamp method using an elastic polymer material, such as PDMS or silicon, as a head.

The plurality of inorganic light-emitting devices 50 may be a light-emitting structure including an n-type semiconductor 58a, an active layer 58c, a p-type semiconductor 58b, a first contact electrode 57a, and a second contact electrode 57b.

Any one of the first contact electrode 57a and the second contact electrode 57b may be electrically connected to the n-type semiconductor 58a, and the other one may be electrically connected to the p-type semiconductor 58b.

The first contact electrode 57a and the second contact electrode 57b may be a flip chip type arranged horizontally toward the same direction (an opposite direction of a light-emitting direction).

Each inorganic light-emitting device 50 may include a light-emitting surface 54 positioned toward the first direction X upon being mounted on the mounting surface 41, a side surface 55, and a bottom surface 56 being opposite to the light-emitting surface 54, and the first contact electrode 57a and the second contact electrode 57b may be formed on the bottom surface 56.

That is, the first and second contact electrodes 57a and 57b of the inorganic light-emitting device 50 may be opposite to the light-emitting surface 54, and accordingly, the first and second contact electrodes 57a and 57b may be positioned in the opposite direction of the light-emitting direction.

The contact electrodes 57a and 57b may face the mounting surface 41, and be electrically connected to the TFT layer 44. Also, the light-emitting surface 54 through which light is irradiated may be positioned in an opposite direction of the direction in which the contact electrodes 57a and 57b are positioned.

Accordingly, light generated by the active layer 58c may be irradiated toward the first direction X through the light-emitting surface 54, without any interference by the first and second contact electrodes 57a and 57b.

That is, the first direction X may be defined as a direction in which the light-emitting surface 54 is positioned to irradiate light.

The first contact electrode 57a and the second contact electrode 57b may be electrically connected respectively to the first pad electrode 44a and the second pad electrode 44b formed on the mounting surface 41 of the substrate 40.

The inorganic light-emitting device 50 may be connected directly to the pad electrodes 44a and 44b through an anisotropic conductive layer 47 or a bonding material such as a solder.

On the substrate 40, the anisotropic conductive layer 47 may be formed to mediate an electrical connection between the contact electrodes 57a and 57b and the pad electrodes 44a and 44b. The anisotropic conductive layer 47 may be formed by applying an anisotropic conductive adhesive on a protective film, and have a structure in which conductive balls 47a is distributed in an adhesive resin. Each conductive ball 47a may be a conductive sphere surrounded by a thin insulating film, and as a result of breaking of the insulating film by pressure, the conductive ball 47a may electrically connect a conductor to another one.

The anisotropic conductive layer 47 may include an anisotropic conductive film (ACF) being in a form of a film, and an anisotropic conductive paste (ACP) being in a form of a paste.

In an embodiment of the disclosure, the anisotropic conductive layer 47 may be provided as an anisotropic conductive film.

Accordingly, the insulating films of the conductive balls 47a may be broken by pressure applied to the anisotropic conductive layer 47 upon mounting of the plurality of inorganic light-emitting devices 50 on the substrate 40, and as a result, the contact electrodes 57a and 57b of the inorganic light-emitting devices 50 may be electrically connected to the pad electrodes 44a and 44b of the substrate 40.

The plurality of inorganic light-emitting devices 50 may be mounted on the substrate 40 through a solder, instead of the anisotropic conductive layer 47. By performing a reflow process after arranging the inorganic light-emitting devices 50 on the substrate 40, the inorganic light-emitting devices 50 may be adhered on the substrate 40.

The plurality of inorganic light-emitting devices 50 may include a red light-emitting device 51, a green light-emitting device 52, and a blue light-emitting device 53. The inorganic light-emitting devices 50 may be mounted in groups including the red light-emitting device 51, the green light-emitting device 52, and the blue light-emitting device 53 on the mounting surface 41 of the substrate 40. The red light-emitting device 51, the green light-emitting device 52, and the blue light-emitting device 53 may form a pixel. In this case, each of the red light-emitting device 51, the green light-emitting device 52, and the blue light-emitting device 53 may form a sub pixel.

The red light-emitting device 51, the green light-emitting device 52, and the blue light-emitting device 53 may be aligned with preset intervals, as in an embodiment of the disclosure. However, the red light-emitting device 51, the green light-emitting device 52, and the blue light-emitting device 53 may be arranged in another form such as a triangle.

The substrate 40 may include a light absorbing layer 44c for absorbing external light to improve contrast. The light absorbing layer 44c may be formed on the entire of the mounting surface 41 of the substrate 40. The light absorbing layer 44c may be formed between the TFT layer 44 and the anisotropic conductive layer 47.

The plurality of display modules 30A to 30P may further include the black matrix 48 formed between the plurality of inorganic light-emitting devices 50.

The black matrix 48 may function to supplement the light absorbing layer 44c formed on the entire of the mounting surface 41 of the substrate 40. That is, the black matrix 48 may improve contrast of a screen by absorbing external light such that the substrate 40 is shown to be black.

The black matrix 48 may have a black color.

According to the current embodiment of the disclosure, the black matrix 48 may be positioned between pixels each formed by the red light-emitting device 51, the green light-emitting device 52, and the blue light-emitting device 53. However, the black matrix 48 may be formed more finely to partition the light-emitting devices 51, 52, and 53 which are sub pixels.

The black matrix 48 may be formed in a shape of a lattice having a horizontal pattern and a vertical pattern to be positioned between the pixels.

The black matrix 48 may be formed by applying a light absorbing ink on the anisotropic conductive layer 47 through an ink-jet process and then hardening the light absorbing ink or by coating the anisotropic conductive layer 47 with a light absorbing film.

That is, the black matrix 48 may be formed in areas between the plurality of inorganic light-emitting devices 50, in which none of the plurality of inorganic light-emitting devices 50 are mounted, on the anisotropic conductive layer 47 formed on the entire of the mounting surface 41.

Each of the plurality of display modules 30A to 30P may include a front cover 70 positioned in the front direction X on the mounting surface 41 of the display module 30A to 30P to cover the mounting surface 41.

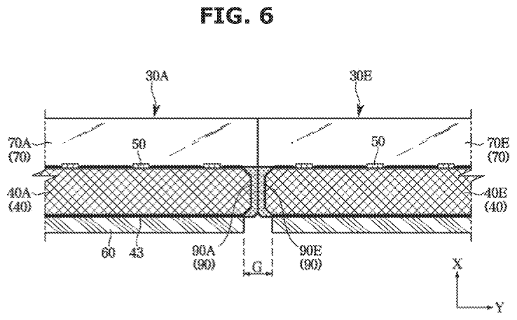

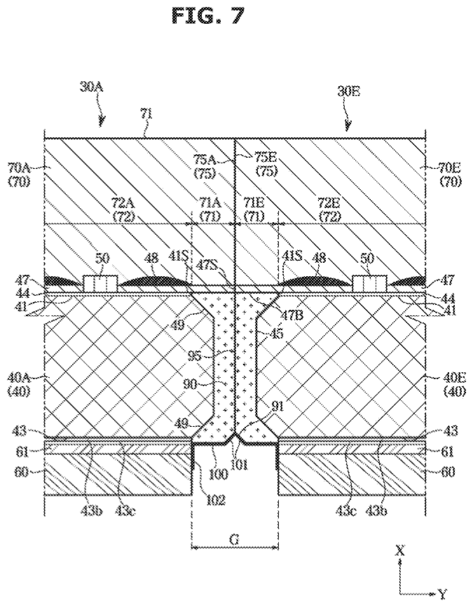

A plurality of front covers 70 may be respectively formed in the first direction X on the plurality of display modules 30A to 30P (see FIGS. 6 and 7).

The plurality of display modules 30A to 30P may be assembled with each other after the front covers 70 are respectively formed on the display modules 30A to 30P. That is, in an example of the first display module 30A and the second display module 30E among the plurality of display modules 30A to 30P, a first front cover 70A may be formed on the mounting surface 41 of the first display module 30A and a second front cover 70E may be formed on the mounting surface 41 of the second display module 30E.

The front cover 70 may cover the substrate 40 to protect the substrate 40 against an external force or outside water.

A plurality of layers of the front cover 70 may be provided as a functional film having optical performance. The plurality of layers will be described in detail, later.

Some of the plurality of layers of the front cover 70 may include a base layer formed of an optical clear resin (OCR). The base layer may support the other layers. The OCR may be in a very transparent state because the OCR has transmittance of 90% or more.

The OCR may improve visibility and image quality by raising transmittance through a low reflection property. That is, in a structure having an air gap, light loss occurs due to a refractive index difference between a film layer and an air layer. However, in a structure having an OCR, such a refractive index difference may be reduced to decrease light loss, resulting in an improvement of visibility and image quality.

That is, the OCR may improve image quality, in addition to protecting the substrate 40.

Some of the plurality of layers of the front cover 70 may include an adhesive layer for adhering the front cover 70 to the mounting surface 41 of the substrate 40.

Generally, the front cover 70 may have a height that is greater than or equal to a preset height in the first direction X which the mounting surface 41 or the light-emitting surface 54 faces.

The front cover 70 formed on the substrate 40 may have a height capable of sufficiently filling a gap that may be formed between the plurality of inorganic light-emitting devices 50 with respect to the front cover 70.

Also, each of the plurality of display modules 30A to 30P may include a metal plate 60 positioned on the rear surface 43 of the substrate 40.

Also, each of the plurality of display modules 30A to 30P may include a rear adhesive tape 61 positioned between the rear surface 43 and the metal plate 60 for adhesion.

The rear adhesive tape 61 may be a double-sided adhesive tape. However, the rear adhesive tape 61 is not limited to a double-sided adhesive tape, and may be an adhesive layer, not a tape. That is, the rear adhesive tape 61 may be an embodiment of a medium for adhering the metal plate 60 to the rear surface 43 of the substrate 40, and the rear adhesive tape 61 may be provided as one of various mediums, without being limited to a tape.

The plurality of inorganic light-emitting devices 50 may be electrically connected to a pixel driving wiring formed on the mounting surface 41, and an upper wiring layer extending through the side surface 45 of the substrate 40 and formed with a pixel driving wiring.

The upper wiring layer may be formed below the anisotropic conductive layer 47. The upper wiring layer may be electrically connected to a side wire 46 formed on the side surface 45 of the substrate 40. The side wire 46 may be provided in a form of a thin film.

Under an assumption that the second direction Y is a left-right direction of the display device 1, being orthogonal to the first direction X toward the front direction of the display device 1, and the third direction Z is an up-down direction of the display device 1, being orthogonal to the first direction X and the second direction Y, the side wire 46 may extend to the rear surface 43 of the substrate 40 in the third direction Z along the chamfer portion 49 and the side surface 45 of the substrate 40 extending in the third direction Z, although not limited thereto.

However, the side wire 46 may extend to the rear surface 43 of the substrate 40 in the second direction Y along the chamfer portion 49 and the side surface 45 of the substrate 40 extending in the second direction Y.

According to an embodiment of the disclosure, the side wire 46 may extend along the edges E of the substrate 40, corresponding to the upper edge 32 and the lower edge 34 of the first display module 30A, although not limited thereto.

However, the side wire 46 may extend along the edges E of the substrate 40, corresponding to at least two edges of the four edges 31, 32, 33, and 34 of the first display module 30A.

The upper wiring layer may be connected to the side wire 46 by an upper connecting pad formed on the edges E of the substrate 40.

The side wire 46 may extend along the side surface 45 of the substrate 40 and be connected to a rear wiring layer 43b formed on the rear surface 43.

An insulating layer 43c may be formed on the rear wiring layer 43b in a direction which the rear surface 43 of the substrate 40 faces, to cover the rear wiring layer 43b.

That is, the plurality of inorganic light-emitting devices 50 may be electrically connected to the upper wiring layer, the side wire 46, and the rear wiring layer 43b, sequentially.

Also, as shown in FIG. 4, the display module 30A may include a driving circuit board 80 for electrically controlling the plurality of inorganic light-emitting devices 50 mounted on the mounting surface 41. The driving circuit board 80 may be a printed circuit board. The driving circuit board 80 may be positioned on the rear surface 43 of the substrate 40 in the first direction X. The driving circuit board 80 may be positioned on the metal plate 60 adhered on the rear surface 43 of the substrate 40.

The display module 30A may include a flexible film 81 connecting the driving circuit board 80 to the rear wiring layer 43b to electrically connect the driving circuit board 80 to the plurality of inorganic light-emitting devices 50.

One end of the flexible film 81 may be connected to a rear connecting pad 43d positioned on the rear surface 43 of the substrate 40 and electrically connected to the plurality of inorganic light-emitting devices 50.

The rear connecting pad 43d may be electrically connected to the rear wiring layer 43b. Accordingly, the rear connecting pad 43d may electrically connect the rear wiring layer 43b to the flexible film 81.

Because the flexible film 81 is electrically connected to the rear connecting pad 43d, the flexible film 81 may transfer power and an electrical signal from the driving circuit board 80 to the plurality of inorganic light-emitting devices 50.

The flexible film 81 may be a flexible flat cable (FFC) or a chip on film (COF).

The flexible film 81 may include a first flexible film 81a and a second flexible film 81b respectively positioned in upper and lower directions with respect to the first direction X which is the front direction, although not limited thereto.

However, the first flexible film 81a and the second flexible film 81b may be positioned in left and right directions with respect to the first direction X, or the first flexible film 81a and the second flexible film 81b may be positioned in at least two directions of the upper, lower, left, and right directions.

A plurality of second flexible films 81b may be provided, although not limited thereto. However, a single second flexible film 81b may be provided, and a plurality of first flexible films 81a may also be provided.

The first flexible film 81a may transfer a data signal from the driving circuit board 80 to the substrate 40. The first flexible film 81a may be a COF, although not limited thereto.

The second flexible film 81b may transfer power from the driving circuit board 80 to the substrate 40. The second flexible film 81b may be a FFC, although not limited thereto.

However, the first flexible film 81a and the second flexible film 81b may be a COF and a FFC, respectively.

The driving circuit board 80 may be electrically connected to the main board 25 (see FIG. 2). The main board 25 may be positioned behind a frame 15, and the main board 25 may be connected to the driving circuit board 80 through a cable behind the frame 15.

On a rear surface of the metal plate 60, a fixing member 82 for adhering the display modules 30A to 30P to the frame 15 may be positioned. The fixing member 82 may be a double-sided tape. The metal plate 60 forming a rear side of the display modules 30A to 30P may be adhered directly to the frame 15 by the fixing member 82 such that the display modules 30A to 30P are supported by the frame 15.

As described above, the metal plate 60 may be in contact with the substrate 40. The metal plate 60 may be adhered to the substrate 40 by the rear adhesive tape 61 positioned between the rear surface 43 of the substrate 40 and the metal plate 60.

FIG. 5 shows the substrate 40 from which some components such as the anisotropic conductive layer 47 are omitted for convenience of descriptions. Also, the side wire 46 may include a coating member 46a for protecting the side wire 46 from the outside, and the coating member 46a is omitted for convenience of description.

The metal plate 60 may be formed of a metal material having high heat conductivity. For example, the metal plate 60 may be formed of an aluminum material.

Heat generated from the TFT layer 44 and the plurality of inorganic light-emitting devices 50 mounted on the substrate 40 may be transferred to the metal plate 60 through the rear adhesive tape 61 along the rear surface 43 of the substrate 40.

Accordingly, heat generated from the substrate 40 may be easily transferred to the metal plate 60 to prevent temperature of the substrate 40 from rising to preset temperature or more.

The plurality of display modules 30A to 30P may be arranged at various locations in a M×N matrix form. The individual display modules 30A to 30P may be movable independently. In this case, each of the display modules 30A to 30P may include the metal plate 60 to maintain a certain level of heat dissipation performance regardless of the locations of the display modules 30A to 30P.

The plurality of display modules 30A to 30P may be arranged in various M×N matrix forms to implement various screen sizes of the display apparatus 1. Accordingly, radiating heat from the individual display modules 30A to 30P by including the metal plate 60 in each of the display modules 30A to 30P as in an embodiment of the disclosure may improve total heat-radiating performance of the display apparatus 1 more than radiating heat through a single metal plate provided for temporary heat radiation.

In a case in which a single metal plate is positioned inside the display apparatus 1, the metal plate may not exist at a location corresponding to a location of some display modules in a front-rear direction while existing at a location where no display module is positioned, resulting in deterioration of heat dissipation efficiency of the display apparatus 1.

That is, all of the individual display modules 30A to 30P may radiate heat through the metal plate 60 positioned in each of the display modules 30A to 30P regardless of the locations, which leads to an improvement of total heat dissipation performance of the display apparatus 1.

The metal plate 60 may be provided in a shape of a quadrangle substantially corresponding to the shape of the substrate 40. An area of the substrate 40 may be larger than or equal to an area of the metal plate 60. According to a parallel arrangement in first direction X of the substrate 40 and the metal plate 60, the four edges E of the substrate 40 being in a shape of a rectangle may correspond to four edges of the metal plate 60 with respect to centers of the substrate 40 and the metal plate 60, or the four edges E of the substrate 40 may be positioned at more outer locations than the four edges of the metal plate 60 with respect to the centers of the substrate 40 and the metal plate 60.

The four edges E of the substrate 40 may be positioned at the more outer locations than the four edges of the metal plate 60. That is, the area of the substrate 40 may be larger than the area of the metal plate 60.

Upon transferring of heat to the individual display modules 30A to 30P, the substrate 40 and the metal plate 60 may be heat-expanded, wherein a degree of expansion of the metal plate 60 may be greater than a degree of expansion of the substrate 40 because the metal plate 60 has a greater coefficient of thermal expansion than the substrate 40.

In a case in which the four edges E of the substrate 40 correspond to the four edges or the metal plate 60 or are positioned at more inner locations than the four edges of the metal plate 60, the edges of the metal plate 60 may protrude to a more outer location than the substrate 40.

As a result, lengths of gaps formed between the display modules 30A to 30P may become non-uniform by thermal expansion of the metal plate 60 of each of the display modules 30A to 30P, and accordingly, recognition of some seams may rise, which deteriorates a sense of unity of a screen of the display panel 20.

However, in a case in which the four edges E of the substrate 40 are positioned at the more outer locations than the four edges of the metal plate 60, the metal plate 60 may not protrude to the more outer location than the four edges E of the substrate 40 although the substrate 40 and the metal plate 60 are heat-expanded, and accordingly, the lengths of the gaps formed between the display modules 30A to 30P may be maintained uniform.

In addition, to maintain constant separation distances of gaps formed between the display modules 30A to 30P, the frame 15 supporting the display modules 30A to 30P may include a front surface having a similar material property to that of the substrate 40. That is, the display modules 30A to 30P may be adhered on the front surface of the frame 15.

According to an embodiment of the disclosure, the area of the substrate 40 may substantially correspond to the area of the metal plate 60. Accordingly, heat generated from the substrate 40 may be uniformly dissipated over the entire area of the substrate 40 without being isolated in some areas.

The metal plate 60 may be adhered on the rear surface 43 of the substrate 40 by the rear adhesive tape 61.

The rear adhesive tape 61 may have a size corresponding to the metal plate 60. That is, an area of the rear adhesive tape 61 may correspond to the area of the metal plate 60. The metal plate 60 may be substantially in a shape of a rectangle, and the rear adhesive tape 61 may also be in a shape of a rectangle correspondingly.

The edges of the metal plate 60 being in the shape of the rectangle may correspond to the edges of the rear adhesive tape 61 being in the shape of the rectangle with respect to a center of the metal plate 60 and the rear adhesive tape 61.

Accordingly, the metal plate 60 and the rear adhesive tape 61 may be easily manufactured as a coupled configuration, thereby increasing manufacturing efficiency of the display apparatus 1.

That is, before a plate is cut into unit pieces to form the metal plate 60, the rear adhesive tape 61 may be adhered on the plate and then the rear adhesive tape 61 and the plate may be cut together into unit pieces to form the metal plate 60, thereby reducing a number of processes.

Heat generated from the substrate 40 may be transferred to the metal plate 60 through the rear adhesive tape 61. Accordingly, the rear adhesive tape 61 may adhere the metal plate 60 on the substrate 40, while transferring heat generated from the substrate 40 to the metal plate 60.

Accordingly, the rear adhesive tape 61 may include a material having high heat dissipation performance.

The rear adhesive tape 61 may include a material having an adhesive property to adhere the substrate 40 to the metal plate 60.

Additionally, the rear adhesive tape 61 may include a material having high heat dissipation performance rather than materials having an adhesive property. Accordingly, the rear adhesive tape 61 may efficiently transfer heat between the substrate 40 and the metal plate 60.

Also, the material having the adhesive property, included in the rear adhesive tape 61, may be a material having higher heat dissipation performance than adhesive materials constituting existing adhesives.

The material having the higher heat dissipation performance may be a material capable of effectively transferring heat because the material has high heat conductivity, high heat transfer performance, and low specific heat.

For example, the rear adhesive tape 61 may include a graphite material, although not limited thereto. However, the rear adhesive tape 61 may be formed of any material having high heat dissipation performance.

Flexibility of the rear adhesive tape 61 may be greater than flexibility of the substrate 40 and the metal plate 60. Accordingly, the rear adhesive tape 61 may be formed of a material having an adhesive property, heat dissipation, and high flexibility. The rear adhesive tape 61 may be a baseless double-sided tape. In this case, the rear adhesive tape 61 may be formed as a single layer of which one side is adhered on the substrate 40 and the other side is adhered on the metal plate 60, without having any base supporting the one side and the other side.

Because the rear adhesive tape 61 includes no base, the rear adhesive tape 61 may include no material interfering with heat conduction, and accordingly, heat dissipation performance may increase. However, the rear adhesive tape 61 is not limited to a baseless double-sided tape, and may be a heat dissipation tape having higher heat dissipation performance than existing double-sided tapes.

The rear adhesive tape 61 may be formed of a material having high flexibility to absorb an external force transferred from the substrate 40 and the metal plate 60. Flexibility of the rear adhesive tape 61 may be higher than flexibility of the substrate 40 and the metal plate 60.

Accordingly, upon transferring an external force generated by changed sizes of the substrate 40 and the metal plate 60 by heat being transferred to the substrate 40 and the metal plate 60 to the rear adhesive tape 61, the rear adhesive tape 61 may be deformed to prevent the external force from being transferred to the other components.

The rear adhesive tape 61 may have a certain thickness in the first direction X. The metal plate 60 may be heat-expanded by heat or cooled to be contracted. In this case, the metal plate 60 may be expanded or contracted in the first direction X and directions that are orthogonal to the first direction X, and accordingly, an external force may be transferred to the substrate 40.

As described above, because the metal plate 60 is formed with a size corresponding to the substrate 40 and covers the entire of the rear surface 43 of the substrate 40, a fixing member 82 may be positioned on a rear surface of the metal plate 60, although not limited thereto.

However, the fixing member 82 may be positioned on the rear surface 43 of the substrate 40. In this case, the substrate 40 may be bonded directly on the frame 15 through the fixing member 82.

The metal plate 60 may cover only a portion of the rear surface 43 of the substrate 40, and the fixing member 82 may be adhered on an area not covered by the metal plate 60 in the rear surface 43 of the substrate 40.

The fixing member 82 may be a double-sided tape. Hereinafter, the front cover 70, a side molding 90, and a grounding member 100 will be described in detail.

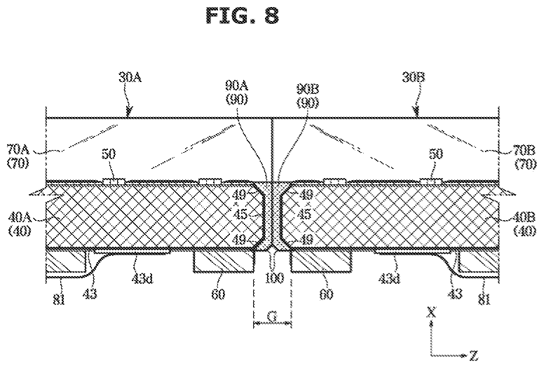

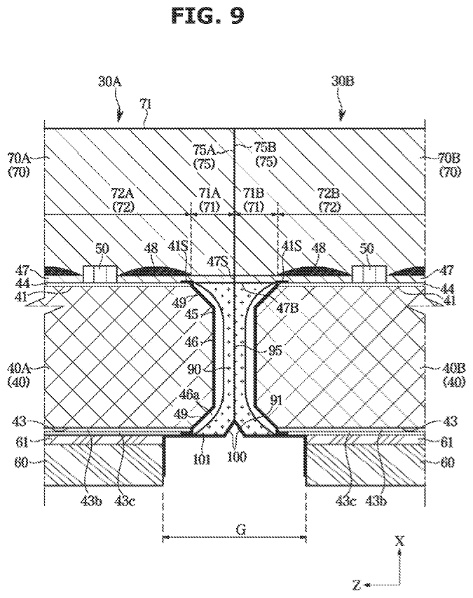

FIG. 6 is a cross-sectional view showing some components of the display device of FIG. 1, taken in the second direction, FIG. 7 is an enlarged cross-sectional view of some components shown in FIG. 6, FIG. 8 is a cross-sectional view showing some components of the display device of FIG. 1, taken in a third direction, and FIG. 9 is an enlarged cross-sectional view of some components shown in FIG. 8.

The front cover 70 may protect the substrate 40 against external forces and reduce visibility of seams formed by the gaps between the plurality of display modules 30A to 30P while improving color deviation between the plurality of display modules 30A to 30P.

Each of the plurality of display modules 30A to 30P may include the side molding 90 positioned between a gap formed between the plurality of display modules 30A to 30P while the plurality of display modules 30A to 30P are arrayed.

To absorb light reflected in the gaps G between the plurality of display modules 30A to 30P, the front covers 70 of the respective display module 30A to 30P may extend to more outer locations than the substrates 40 of the plurality of display module 30A to 30P. Side ends 75 of each front cover 70 may extend to a more outer location than the mounting surface 41.

The front cover 70 may extend to a more outer location than an edge (or a side end) 41e of the mounting surface 41 of the substrate 40 in the second direction Y and the third direction Z (see FIG. 5).

Substantially, the gaps between the display modules 30A to 30P may be made between side surfaces 45 of the substrates 40 of the display modules 30A to 30P. However, a gap G in an embodiment of the disclosure means a non-display area that may be made between the display modules 30A to 30P, and accordingly, the gap G formed between the plurality of display modules 30A to 30P may be understood as a space formed between an edge 41S of a mounting surface 41 of a substrate 40 of one of the display modules 30A to 30P and an edge 41S of a mounting surface 41 of a substrate 40 of a neighboring display module 30A to 30P.

Accordingly, the gap G formed between the plurality of display modules 30A to 30P means a space formed between an edge 41S of a mounting surface 41 of one of the display modules 30A to 30P and an edge 41S of a mounting surface 41 of a neighboring display module 30A to 30P in the second direction Y or the third direction Z.

The front covers 70 extending from the respective display modules 30A to 30P may be positioned at the gaps G between the plurality of display modules 30A to 30P to absorb light irradiated into the gaps G or light reflected from the gaps G, thereby minimizing recognition of seams.

Also, light irradiated into the gaps G may be absorbed in the side molding 90 of the plurality of display modules 30A to 30P, positioned between the gaps G, thereby minimizing recognition of seams, which will be described below.

As shown in FIGS. 6 and 7, the front cover 70 may extend to a more outer location than the substrate 40 in the second direction Y. The front cover 70 may extend to a more outer location than the side surface 45 and the chamfer portion 49 in the second direction Y.

According to an embodiment of the disclosure, while an edge of the substrate 40, corresponding to a right edge 31 of the first display module 30A is described, the front cover 70 may extend to a more outer location than the four edges E of the substrate 40 in the second direction Y or the third direction Z.

That is, the side ends 75 of the front cover 70, which correspond to edges of the front cover 70, may extend to an outer area of the substrate 40, that is, to a more outer area of the mounting surface 41 than the four edges E of the substrate 40 in the second direction Y or the third direction Z.

The front cover 70 may include a plurality of layers having different optical properties. The plurality of layers may be provided in a structure in which the layers are stacked in the first direction X.

The plurality of layers may constitute the front cover 70 by being adhered with each other in the first direction X.

One of the plurality of layers may be an anti-glare layer, although not limited thereto. However, one of the plurality of layers may be an anti-reflective layer or a mixed layer of an anti-glare layer and an anti-reflective layer.

Another one of the plurality of layers may be a light transmittance adjustable layer, although not limited thereto. However, the layer may be a layer having another physical property or including another material, or a layer having another function. For example, the layer may be a circularly polarized layer.

However, a single layer, instead of the plurality of layers, may be provided. The single layer may be a layer capable of implementing all functions of the plurality of layers.

As described above, the front cover 70 may include an adhesive layer. The adhesive layer may be positioned at a hindmost location of the plurality of layers in the first direction X and adhered on the mounting surface 41. The adhesive layer may have a height that is greater than or equal to a preset height in the first direction X which the mounting surface 41 or the light-emitting surface 54 faces.

The reason may be to cause the adhesive layer adhered on the substrate 40 to sufficiently fill a gap that may be formed between the adhesive layer and the plurality of inorganic light-emitting devices 50.

However, the adhesive layer is not limited to the embodiment of the disclosure, and the adhesive layer may be positioned as a separate component from the front cover 70 between the front cover 70 and the mounting surface 41 to adhere the front cover 70 with the mounting surface 41.

Accordingly, because the front cover 70 is adhered with the mounting surface 41 while being in close contact with the mounting surface 41 and protects components mounted on the mounting surface 41, the display module 30 may adhere the front cover 70 directly to the substrate 40 without any additional molding component formed between the front cover 70 and the substrate 40.

The front cover 70 may diffuse and reflect light received from the outside to prevent the light from being specularly reflected to dazzle a user's eyes.

By diffusing and reflecting light received from the outside, a glaring phenomenon may be reduced, and accordingly, contrast of a screen displayed on the display panel 20 may be improved.

Also, the front cover 70 may reduce transmittance of incident external light or external light reflected from the substrate 40 and the gap G.

The front cover 70 according to an embodiment of the disclosure may include a material capable of reducing transmittance of light, to absorb at least one part of light transmitted toward the substrate 40 or light reflected from the substrate 40 and then traveling toward the first direction X.

Some of a plurality of substrates may be manufactured with different colors due to a matter of process. Accordingly, substrates having different unique colors may be tiled to constitute a single display panel.

As described above, the front cover 70 according to an embodiment of the disclosure may absorb at least one part of light reflected from the substrate 40 and transmitted to the outside, thereby raising a sense of unity of a screen displayed on the display panel 20.

That is, the front cover 70 may reduce color deviation generated during processes of the plurality of display modules 30A to 30P by lowering transmittance with respect to external light.

The front cover 70 may prevent external light which entered the display panel 20 from the outside from being transmitted to the substrate 40, and additionally absorb a part of light which entered the display panel 20 from the outside or a part of external light reflected from the substrate 40 and then transmitted to the outside of the display panel 20, thereby improving contrast of a screen that is displayed on the display panel 20. Such different optical actions may be respectively implemented by the plurality of layers described above.

That is, the front cover 70 may be positioned in front of the substrate 40 in the first direction X to improve contrast that may deteriorate by external light in a screen displayed on the display panel 20.

As described above, in the display module 30 according to an embodiment of the disclosure, the front cover 70 may extend to the outside of the substrate 40 in the second direction Y.

Accordingly, a part of light that has entered the gap G formed between the plurality of display modules 30A to 30P may be blocked by at least one portion of the front cover 70 positioned in the gap G, and at least a part of external light that has entered the gap G or reflected in the gap G may be absorbed by the front cover 70 positioned in the gap G and thus be not transmitted to the outside. Accordingly, visibility of a seam that is formed in the gap G may deteriorate, and due to the deterioration of the visibility of the seam, a sense of unity of a screen that is displayed on the display panel 20 may be improved.

The side end 75 of the front cover 70 in the second direction Y may be positioned at a more outer location than the edge 41S of the mounting surface 41 in the second direction Y, or in the gap G.

Accordingly, the front cover 70 may include a first area 71 positioned at the more outer location than the edge 41S of the mounting surface 41 in the second direction Y or in the gap G, and a second area 72 above the mounting surface 41.

The first area 71 and the second area 72 of the front cover 70 may be partitioned by the gap G in the second direction Y.

Because the first area 71 of the front cover 70 is positioned in the gap G, external light irradiated toward the gap G may be blocked by the first area 71 of the front cover 70 or light reflected in the gap G may be prevented from being irradiated to the outside. Accordingly, visibility of a seam which is a boundary between the plurality of display modules 30A to 30P and which may be formed by the gap G may be reduced, resulting in an improvement of a sense of unity of the display panel 20.

Because the front cover 70 extends to the more outer location than the four edges 41S of the mounting surface 41 of the substrate 40, as described above, visibility of seams that may be formed at the edges of the plurality of display modules 30A to 30P may be reduced.

In the example of the first display module 30A and the second display module 30E, a first area 71A of a first front cover 70A extending from the first display module 30A may be positioned in a gap G formed between the first display module 30A and the second display module 30E.

In the gap G, neighboring side ends 75A and 75E of the front covers 70A and 70E of the first and second display modules 30A and 30E may be positioned.

Also, in the gap G, the side surfaces 45 and chamfer portions 49 of the first and second display modules 30A and 30E may be positioned.

A second area 72A of the first front cover 70A may be positioned above the mounting surface 41 of the first display module 30A.

A first area 71E of the second cover 70E extending from the second display module 30E may be positioned in the gap G formed between the first display module 30A and the second display module 30E, and a second area 72E of the second front cover 70E may be positioned above the mounting surface 41 of the second display module 30E.

That is, in the gap G formed between the first display module 30A and the second display module 30E, the first areas 71A and 71E of the first and second front covers 70A and 70E may be positioned side by side in the second direction Y.

Lengths in the second direction Y of the first areas 71A and 71E of the first and second front covers 70A and 70E may be substantially smaller than or equal to half of a length of the gap G. Each of the first area 71A of the first front cover 70A and the first area 71E of the second front cover 70E may have a length of ½ of the length of the gap G.

Accordingly, a sum of the lengths of the first areas 71A and 71E of the first and second front covers 70A and 70E arranged side by side in the second direction Y may substantially correspond to or be smaller than the length of the gap G. A sum of the lengths of the first areas 71A and 71E of the first and second front covers 70A and 70E may be equal to the length of the gap G.

Accordingly, the side end 75A of the first front cover 71A, which is adjacent to the second front cover 70E, may be in contact with the side end 75E of the second front cover 70E, which is adjacent to the first front cover 70A, while facing the side end 75E of the second front cover 70E.

Accordingly, the first display module 30A and the second display module 30E may be tiled without any space between the first area 71A of the first front cover 70A and the first area 71E of the second cover 70E.

Additionally, a side end 47S of the anisotropic conductive layer 47 of the display module 30 may be aligned with the side end 75 of the front cover 70 in the first direction X. The reason may be because the anisotropic conductive layer 47 and the front cover 70 of the display module 30 are cut and processed simultaneously during a process, which will be described below.

Accordingly, a side end 47S of an anisotropic conductive layer 47 of the first display module 30A, which is adjacent to the second display module 30E, may be in contact with a side end 47S of an anisotropic conductive layer 47 of the second display module 30E, which is adjacent to the first display module 30A, while facing the side end 47S of the anisotropic conductive layer 47 of the second display module 30E.

As described above, the first area 71A of the first front cover 70A and the first area 71E of the second front cover 70E may be positioned above the gap G between the first display module 30A and the second display module 30E.

External light that has entered the display panel 20 may be diffused and reflected to the outside of the display panel 20 by being transmitted through the first areas 71A and 71E of the first and second front covers 70A and 70E, or a part of the external light may be absorbed in the first areas 71A and 71E. Accordingly, an amount of light arrived at the gap G may be reduced, and visibility of a boundary between the first display module 30A and the second display module 30E by the gap G may be reduced.

Also, light reflected in the gap G and then traveling to the outside of the display panel 20 may be diffused and reflected to the outside of the display panel 20 while being transmitted through the first areas 71A and 71E of the first and second front covers 70A and 70E, or a part of the light may be absorbed in the first areas 71A and 71E. Accordingly, an amount of light transmitted to the outside of the display panel 20 may be reduced, which reduces visibility of the boundary between the first display module 30A and the second display module 30E, caused by the gap G.

That is, by reducing an amount of external light entering the gap G formed between the plurality of display modules 30A to 30P while absorbing at least one part of the external light reflected in the gap G, a sense of unity of a screen displayed on the display panel 20 may be improved.

Additionally, although a substrate 40A of the first display module 30A and a substrate 40E of the second display module 30E have different colors, at least one part of external light reflected from the substrates 40A and 40E may be absorbed in the first and second front covers 70A and 70E. Accordingly, unique colors of the substrates 40A and 40E may be not recognized from the outside, which improves a sense of unity of a screen displayed on the display panel 20.

The display module 30A may include the side molding 90 positioned below the front cover 70 in the direction which the mounting surface 41 faces and provided on the side surface 45 of the substrate 40.

The side molding 90 may be positioned in a space defined by a lower surface of the anisotropic conductive layer 47, corresponding to a lower surface of the first area 71 of the front cover 70 in the first direction X, and the side surface 45 of the substrate 40 in the second direction Y.

The side molding 90 may be adhered to the side surface 45 and the lower surface 47B of the anisotropic conductive layer 47 positioned at the first area 71.

The side molding 90 may be adhered to all the lower surface 47B of the anisotropic conductive layer 47 positioned at the first area 71, the chamfer portion 49 positioned between the side surface 45 and the mounting surface 41, the side surface 45, and the chamfer portion 49 positioned between the side surface 45 and the rear surface 43.

That is, the side molding 90 may surround the entire of the chamfer portion 49 formed between the mounting surface 41 and the side surface 45 and the lower surface of the anisotropic conductive layer 47, as well as the side surface 45. Because the side molding 90 surrounds the chamfer portion 49 formed between the mounting surface 41 and the side surface 45, the lower surface 47B of the anisotropic conductive layer 47 positioned at the first area 71, and the side surface 45, the side molding 90 may fill all spaces that may be made between the substrate 40 and the front cover 70.

Accordingly, the side molding 90 may seal the side surface 45 from the outside, and prevent foreign materials or water from entering the space formed by the substrate 40, the front cover 70, and the anisotropic conductive layer 47.

The side molding 90 may support the lower surface 47B of the anisotropic conductive layer 47 positioned at the first area 71, the chamfer portions 49 of the substrate 40, and the side surface 45 of the substrate 40.

As described above, while the front cover 70 is adhered to the substrate 40, adhesion between the front cover 70 and the substrate 40 may be enhanced by the side molding 90. Accordingly, the side molding 90 may prevent the front cover 70 from departing from the substrate 40.

That is, reliability of the display module 30A may rise by the side molding 90.

As described above, the side surface 45 of the substrate 40 may correspond to the four edges 41S of the mounting surface 41, and the first area 71 of the front cover 70 may extend to more outer locations than the four edges 41S of the mounting surface 41 in the second direction Y and the third direction Z in which the mounting surface 41 extends.

The side molding 90 may surround the side surface 45 corresponding to each of the four edges 41S of the mounting surface 41, along the four edges 41S of the mounting surface 41.

That is, the side molding 90 may seal all edges of a portion at which the substrate 40 is adhered with the front cover 70.

Accordingly, adhesion between the front cover 70 and the substrate 40 may be improved, and the front cover 70 and the side surface 45 of the substrate 40 may be protected from an external force.

Also, outside water or a foreign material may be prevented from entering between the substrate 40 and the front cover 70, as described above. In addition, upon formation of a gap between the substrate 40 and the front cover 70 due to degradation of adhesion, outside water or a foreign material may be prevented from entering the gap.

The side molding 90 may surround all the four edges E of the substrate 40 along the side surface 45 of the substrate 40 to seal between the substrate 40 and the front cover 70.

Accordingly, the side molding 90 may prevent a foreign material or water entered the substrate 40 in all directions from permeating into the substrate 40 and the front cover 70.

Also, current may flow to a plurality of electronic components mounted on the substrate 40 by an electrostatic discharge which may be generated on the display modules 30A to 30P to damage the electronic components, and the side molding 90 may seal the substrate 40 from the outside and thus block charges generated by an electrostatic discharge from entering the substrate 40, to prevent the electronic components from being damaged.

That is, because the substrate 40 is sealed by the front cover 70 and the side molding 90, charges generated by an electrostatic discharge may be prevented from passing through the front cover 70 and the side molding 90 and thus flowing to the substrate 40. Also, charges flowing on the front cover 70 and the side molding 90 may be guided to the metal plate 60 being in contact with the side molding 90 by the grounding member 100 which will be described below, thereby providing a path for current generated by an electrostatic discharge. Accordingly, electrostatic discharge (ESD) resistant pressure of the electronic components mounted on the substrate 40 may be improved.

Typically, a process of dispensing a resin capable of absorbing light and made of a nonconductive material between the side surface 45 and the front cover 70 and then hardening the resin has been performed to cover the side surface 45 of the substrate 40.

However, during the dispensing process, process errors have caused problems in which a gap is made between the side surface 45 and the resin, between the front cover 70 and the substrate 40, between the anisotropic conductive layer 47 and the front cover 70, or between the anisotropic conductive layer 47 and the mounting surface 41 or in which bubbles are generated while the resin is hardened, resulting in penetration of foreign materials from the outside or deterioration of ESD resistance. Also, before the resin is dispensed, the side surface 45 may be exposed to the outside, and accordingly, the side surface 45 or the side wire 46 positioned on the side surface 45 may be damaged.

In the display modules 30A to 30P according to an embodiment of the disclosure, because the side molding 90 is injection-molded onto the substrate 40 on which various wiring works have been completed, complete sealing between the side surface 45 and the side molding 90 may be achieved while the side surface 45 is protected from an initial stage of the process, and a process of adhering the anisotropic conductive layer 47 and the front cover 70 with the substrate 40 in a state in which the side surface 45 is covered with the side molding 90 may be induced to thereby minimize a space that may be generated between the side molding 90 and the anisotropic conductive layer 47 and the front cover 70 during the process.

That is, in a process of the display modules 30A to 30P, because before a process of adhering the anisotropic conductive layer 47 and the front cover 70 with the substrate 40, the side molding 90 is injection-molded onto the side surface 45 of the substrate 40 to seal the side surface 45 and the side wire 46 positioned on the side surface 45 by the side molding 90, defective processes of the display modules 30A to 30P, which are caused by the process errors, may be minimized, which will be described in detail below.

As described above, the side molding 90 may be positioned below the front cover 70 in the direction which the mounting surface 41 faces. That is, the side molding 90 may be not positioned above the lower surface of the front cover 70 in the first direction X.

A front end of the side molding 90 in the first direction X may be in contact with the lower surface 47B of the anisotropic conductive layer 47 at the first area 71, and may be not positioned before the lower surface of the first area 71 in the first direction X.

The reason may be not to locate the side molding 90 on a traveling path of light emitted from the inorganic light-emitting devices 50.

In a case in which at least one portion of the side molding 90 is positioned before the lower surface 76 in the first direction X or before the front cover 70 in the first direction X, the at least one portion of the side molding 90 may be positioned on a traveling path of light traveling forward through the front cover 70.

That is, the side molding 90 may absorb or diffuse and reflect a part of traveling light to distort an area of an image displayed on the display panel 20.

However, because the side molding 90 according to an embodiment of the disclosure is positioned behind the front cover 70 in the first direction X, the side molding 90 may not limit traveling of light emitted from the plurality of light-emitting devices 50, thereby improving image quality of the display panel 20.

The side end 75 of the front cover 70 in the second direction Y and a side end 95 of the side molding 90 in the second direction Y may be aligned in the first direction X. Also, the side end 75 of the front cover 70, the side end 47S of the anisotropic conductive layer 47, and the side end 95 of the side molding 90 may be aligned in the first direction X.

The reason may be because the front cover 70, the anisotropic conductive layer 47, and the side molding 90 are cut simultaneously in a process of manufacturing the display module 30A.

That is, a space that may be formed between the plurality of display modules 30A to 30P upon an arrangement of the plurality of display modules 30A to 30P may be reduced, and visibility of a seam, which is caused by the space between the plurality of display modules 30A to 30P, may be minimized.

The side molding 90 may include a light absorbing material. For example, the side molding 90 may be formed of an opaque or translucent material.

Also, the side molding 90 may include a photosensitive material. For example, the side molding 90 may seal the side surface 45 through a process in which a photosensitive optical clear resin (OCR) is insert-injected. The photosensitive material may change physical properties to show a dark color by receiving external light, such as ultraviolet (UV) light, having a wavelength that is different from a wavelength of visible light.

Accordingly, by irradiating UV light to the side molding 90 during a manufacturing process to color the side molding 90 with a dark color, the side molding 90 may be provided as a light absorbing member.

The side molding 90 may have a dark color. The side molding 90 may have a darker color than the front cover 70.

The side molding 90 may have a similar color to that of the black matrix 48.

Accordingly, light entered the side molding 90 may be absorbed in the side molding 90 without being reflected, by the light absorbing member of the side molding 90.

The side molding 90 may be positioned in the gap G formed between the plurality of display modules 30A to 30P, together with the first area 71 of the front cover 70, upon an arrangement of the plurality of display modules 30A to 30P.

Accordingly, by absorbing light entered the gap G, an amount of light reflected and then emitted to the outside among the light entered the gap G may be minimized. Therefore, visibility of a seam formed by the gap G between the plurality of display modules 30A to 30P may be reduced.

In the example of the first display module 30A and the second display module 30E, the first side cover 90A of the first display module 30A and the second side cover 90E of the second display module 30E may be positioned in the gap G formed between the first display module 30A and the second display module 30E, together with the first area 71A of the first front cover 70A and the first area 71E of the second cover 70E.

In the gap G, the side end 95 being adjacent to the second display module 30E in the side molding 90 of the first display module 30A and the side end 95 being adjacent to the first display module 30A in the side molding 90 of the second display module 30E may be positioned together with the neighboring side ends 75A and 75E of the front covers 70A and 70E of the first and second display modules 30A and 30E.

The neighboring side ends 75A and 75E of the first and second front covers 70A and 70E may be in contact with each other while facing each other, and the side end 95 being adjacent to the second display module 30E in the side molding 90 of the first display module 30A, and the side end 95 being adjacent to the first display module 30A in the side molding 90 of the second display module 30E may be in contact with each other while facing each other. The neighboring side ends 75A and 75E of the first and second front covers 70A and 70E may be parallel to and in contact with the side end 95 being adjacent to the second display module 30E in the side molding 90 of the first display module 30A and the side end 95 being adjacent to the first display module 30A in the side molding 90 of the second display module 30E.

That is, in the gap G formed between the first display module 30A and the second display module 30E, the neighboring side ends 75A and 75E of the first and second front covers 70A and 70E may be positioned in parallel to the side end 95 being adjacent to the second display module 30E in the side molding 90 of the first display module 30A and the side end 95 being adjacent to the first display module 30A in the side molding 90 of the second display module 30E.

As described above, external light entered the display panel 20 may be diffused and reflected to the outside of the display panel 20 by being transmitted through the first areas 71A and 71E of the first and second front covers 70A and 70E, or a part of the external light may be absorbed in the first areas 71A and 71E of the first and second front covers 70A and 70E. Accordingly, an amount of light arrived at the gap G may be reduced.

In addition, a part of light arrived at the gap G may be absorbed in the side molding 90 of the first display module 30A and the side molding 90 of the second display module 30E, positioned in the gap G, and accordingly, visibility of a boundary between the first display module 30A and the second display module 30E may be reduced.

That is, by reducing an amount of external light entering the gap G formed between the plurality of display modules 30A to 30P and additionally absorbing light arrived at the gap G, a sense of unity of a screen displayed on the display panel 20 may be improved.

In addition, light reflected from the side molding 90 without being absorbed in the side molding 90 of each of the first and second display modules 30A and 30E and then traveling to the outside of the display panel 20 may be diffused and reflected to the outside of the display panel 20 by being transmitted through the first areas 71A and 71E of the first and second front covers 70A and 70E, or a part of the light may be absorbed in the first areas 71A and 71E. Accordingly, an amount of light transmitted to the outside of the display panel 20 may be reduced, and thus, visibility of the boundary between the first display module 30A and the second display module 30E, caused by the gap G, may be reduced.

Because the side molding 90 is positioned in the gap G formed between the plurality of display modules 30A to 30P upon an arrangement of the plurality of display modules 30A to 30P, as described above, the side molding 90 may absorb light arrived at the gap G to reduce visibility of a seam, caused by the gap G.

In the above-described example, the front cover 70 may diffuse and reflect, absorb, or circularly polarize a part of light entered the display panel 20, or change a reflection direction of the part of the light, thereby reducing an amount of light that arrives at the substrate 40, although not limited thereto.

However, the front cover 70 may be formed of a transparent material to transmit light without any deformation. In this case, visibility of the boundary between the plurality of display modules 30A to 30P, caused by the gap G, may be reduced by the side molding 90 positioned between the plurality of display modules 30A to 30P.

Because the side molding 90 is formed of a light absorbing material, as described above, a part of the light emitted from the plurality of inorganic light-emitting devices 50 may be absorbed in the side molding 90 in a case in which at least one portion of the side molding 90 is positioned before the front cover 70 in the first direction X. Accordingly, a part of a screen displayed on the display panel 20 may appear dark.

However, because the side molding 90 according to an embodiment of the disclosure is positioned below the front cover 70 in the first direction X below the lower surface of the first area 71, the side molding 90 may not absorb light emitted from the plurality of inorganic light-emitting devices 50, and accordingly, brightness of an image displayed on the display panel 20 may be uniform.

As shown in FIGS. 8 and 9, the front cover 70 may extend to the more outer location than the substrate 40 in the third direction Z. The front cover 70 may extend to the more outer location than the side surface 45 and the chamfer portion 49 in the third direction Z.

The side end 75 of the front cover 70 in the third direction Z may be positioned at the more outer location than the edge 41S of the mounting surface 41 in the third direction Z, or in the gap G.

The first area 71 and the second area 72 of the front cover 70 may be partitioned by the gap G in the third direction Z.

In an example of the first display modules 30A and the third display module 30B, the first area 71A of the first front cover 70A extending from the first display module 30A may be positioned in a gap G formed between the first display module 30A and the third display module 30B.

In the gap G, neighboring side ends 75A and 75B of the front covers 70A and 70B of the first and third display modules 30A and 30B may be positioned.

Also, the side surfaces 45 and chamfer portions 49 of the first and third display modules 30A and 30B may be positioned in the gap G.

A first area 71B of a third front cover 70B extending from the third display module 30B may be positioned in the gap G formed between the first display module 30A and the third display module 30B, and a second area 72B of the third front cover 70B may be positioned above the mounting surface 41 of the third display module 30B.

That is, in the gap G between the first display module 30A and the third display module 30B, the first areas 71A and 71B of the first and third front covers 70A and 70B may be positioned side by side in the third direction Z.

External light entered into the display panel 20 may be diffused and reflected to the outside of the display panel 20 by being transmitted through the first areas 71A and 71B of the first and third front covers 70A and 70B, or a part of the external light may be absorbed in the first areas 71A and 71B. Accordingly, an amount of light arrived at the gap G may be reduced, and visibility of a boundary between the first display module 30A and the third display module 30B, caused by the gap G, may be reduced.

Also, light reflected in the gap G and then traveling to the outside of the display panel 20 may be diffused and reflected to the outside of the display panel 20 by being transmitted through the first areas 71A and 71B of the first and third front covers 70A and 70B, or a part of the light may be absorbed in the first areas 71A and 71B. Accordingly, an amount of light transmitted to the outside of the display panel 20 may be reduced, and visibility of the boundary between the first display module 30A and the third display module 30B, caused by the gap G, may be reduced.

As described above, the side molding 90 may be positioned in a space formed in the side surface 45 of the substrate 40 in the second direction Y and the third direction Z.

On the side surface 45 of the substrate 40 extending in the third direction Z, the side wire 46 may be positioned.

The side wire 46 may include a coating member 46a for protecting the side wire 46 from the outside. The coating member 46a may be applied or coated on the side wire 46 to prevent the side wire 46 from being exposed to the outside.

The side molding 90 may surround the side wire 46, as well as the side surface 45 and the chamfer portion 49 positioned toward the third direction Z. Accordingly, the side molding 90 may protect the side wire 46 from an external force and prevent a foreign material or water from entering the side wire 46.

That is, the side molding 90 may surround the side wire 46 extending along the side surface 45 in the third direction Z by surrounding the lower surface 76 of the first area 71 and the side surface 45 corresponding to the four edges 41S of the mounting surface 41 along the four edges 41S of the mounting surface 41.

Accordingly, adhesion between the front cover 70 and the substrate 40 may be improved, and the front cover 70, the side surface 45 of the substrate 40, and the side wire 46 may be protected from an external force.

The side end 75 of the front cover 70 in the third direction Z and the side end 95 of the side molding 90 in the third direction Z may be aligned in the first direction X. The side end 75 of the front cover 70 and the side end 95 of the side molding 90 may be aligned in a direction that is in parallel to the first direction X.

Also, the side end 75 of the front cover 70, the side end 47S of the anisotropic conductive layer 47, and the side end 95 of the side molding 90 in the third direction Z may be aligned in the first direction X.

In the example of the first display module 30A and the third display module 30B, the side molding 90 of the first display module 30A and the side molding 90 of the third display module 30B may be positioned in the gap G formed between the first display module 30A and the third display module 30B, together with the first area 71A of the first front cover 70A and the first area 71B of the third front cover 70B.

In the gap G, the neighboring side end portions 95 of the side moldings 90 of the first and third display modules 30A and 30B may be positioned together with the neighboring side ends 75A and 75B of the front covers 70A and 70B of the first and third display modules 30A and 30B.

The neighboring side ends 75A and 75B of the front covers 70A and 70B may be in contact with the neighboring side ends 95 of the side moldings 90 while facing the neighboring side ends 95 of the side moldings 90.

The neighboring side ends 75A and 75B of the front covers 70A and 70B may be in contact with the neighboring side ends 95 of the side moldings 90 while being in parallel to the neighboring side ends 95 of the side moldings 90.

That is, in the gap G formed between the first display module 30A and the third display module 30B, the first areas 71A and 71B of the first and third front covers 70A and 70B may be positioned in parallel to the side moldings 90 of the first and third display modules 30A and 30B in the third direction Z.

Because the side end 75 of the front cover 70 and the side molding 90 of the side molding 90 in the third direction Z are aligned in the first direction X, a space that may be formed between the first and third display modules 30A and 30B upon an arrangement of the first and third display modules 30A and 30B may be minimized.

In the gap G formed between the first display module 30A and the third display module 30B, the first areas 71A and 71B of the first and third front covers 70A and 70B may be arranged in parallel to the side moldings 90 of the first and third display modules 30A and 30B in the third direction Z.

In the gap G formed between the first display module 30A and the third display module 30B, the first area 71A of the first front cover 70A and the first area 71B of the third front cover 70B may be arranged, and the side moldings 90 of the first and third display modules 30A and 30B may be arranged behind the first areas 71A and 71B in the first direction X.

As described above, external light entered into the display panel 20 may be diffused and reflected to the outside of the display panel 20 by being transmitted through the first areas 71A and 71B of the first and third front covers 70A and 70B, or a part of the external light may be absorbed in the first areas 71A and 71B. Accordingly, an amount of light arrived at the gap G may be reduced.

In addition, light arrived at the gap G may be absorbed in the side moldings 90 of the first and third display modules 30A and 30B, positioned in the gap G, and accordingly, visibility of the boundary between the first display module 30A and the third display module 30B may be reduced.

Light reflected from the side moldings 90 and then traveling to the outside of the display panel 20 without being absorbed in the side moldings 90 may be diffused and reflected to the outside of the display panel 20 by being transmitted through the first areas 71A and 71B of the first and third front covers 70A and 70B, or a part of the light may be absorbed in the first areas 71A and 71B. Accordingly, an amount of light transmitted to the outside of the display panel 20 may be reduced, and visibility of the boundary between the first display module 30A and the third display module 30B, caused by the gap G, may be reduced.

A process of injecting the side molding 90 may be performed on all the four edges E of the substrate 40. Accordingly, the side molding 90 may be formed, for example, by insert-injection through a mold to cover the entire of a second area 45b of the side surface 45 of the substrate 40.

The front cover 70 may be formed of a non-conductive material through which no charges are transmitted.

The side molding 90 may be formed of a non-conductive material through which no charges are transmitted.

Because the front cover 70 and the side molding 90 are formed of a non-conductive material, a major part of the current applied to the front cover 70 or the side molding 90 may flow on the front cover 70 and the side molding 90 without being transmitted through the front cover 70 and the side molding 90.

The metal plate 60 may be formed of a material having great capacitance, and function as a ground. Accordingly, upon applying current to the metal plate 60, the metal plate 60 may be maintained at a constant potential, the current applied to the metal plate 60 may be absorbed in the metal plate 60, and no current may flow to the substrate 40 through the metal plate 60.

That is, in the display device 1, the entire side wire 46 of the substrate 40 may be surrounded by the side molding 90, and accordingly, the side wire 46 may be sealed not to be exposed to the outside. Accordingly, static electricity discharged from the side surface 45 of the substrate 40 may not enter the side wire 46 due to the side molding 90.

To prevent current generated by an electrostatic discharge from entering the display module 30 to damage electronic components installed inside the display module 30 in a process before the display module 30 is coupled to the frame 15 to be assembled into the display device 1, the display module 30 may include the front cover 70, the side molding 90, and the metal plate 60 to absorb an electrical impact.

Accordingly, each of the display modules 30A to 30P may independently include a component for blocking current generated by an electrostatic discharge from entering components mounted on the substrate 40, and the current generated by the electrostatic discharge may be easily guided to the metal plate 60 which is a ground component along the front cover 70 and the side molding 90 sealing the substrate 40 on each of the display modules 30A to 30P without entering the components mounted on the substrate 40.

The display device 1 according to an embodiment of the disclosure may further include the grounding member 100 positioned on a lower surface of the side molding 90 in the second direction Y and the third direction Z of the display module 30 and formed of a material having higher conductivity than the front cover 70 and the side molding 90.

The grounding member 100 may easily guide static electricity to the metal plate 60 although the display modules 30A to 30P are insufficiently sealed due to a defect caused during a manufacturing process.

Because the display modules 30A to 30P have the same configuration, only the first display module 30A will be described as a representative, below. The grounding member 100 may be positioned on the lower surface of the side molding 90 and be in contact with the metal plate 60, as shown in FIGS. 7 and 9.

The side molding 90 may include a chamfer portion 91 formed between the lower surface and the side end 95. The chamfer portion 91 may be provided in a chamfering shape to be inclined with respect to the side end 95.

A first end 101 of the grounding member 100 may be positioned on the chamfer portion 91 of the side molding 90, and a second end 102 of the grounding member 100 may be in contact with a side surface of the metal plate 60 to be grounded to the metal plate 60.

The grounding member 100 may surround all the lower surfaces and chamfer portions 91 of the side moldings 90 formed on the four edges E of the substrate 40.

The grounding member 100 may be made of a metal material, and may be made of a higher conductive material than the side molding 90.

Because the first end 101 of the grounding member 100 is positioned on the chamfer portion 91 of the side molding 90, the grounding member 100 may be provided at a more inner location than the side end 95 of the side molding 90 in the second direction Y or the third direction Z.

Accordingly, upon an arrangement of the display modules 30A to 30P, the grounding member 100 may be not positioned in the gap G formed between the display modules 30A to 30P.

Accordingly, upon an arrangement of the display modules 30A to 30P, each grounding member 100 may prevent formation of any additional space between the display modules 30A to 30P.

That is, because the side end 75 of the front cover 70, the side end 47S of the anisotropic conductive layer 47, and the side end 95 of the side molding 90 are aligned in the first direction X, the side ends of the display modules 30A to 30P may be adhered to each other without any space between the display modules 30A to 30P upon an arrangement of the display modules 30A to 30P.

In a case in which the grounding member 100 is positioned at the side ends of the display modules 30A to 30P, the grounding member 100 may form a space between the display modules 30A to 30P. However, because the grounding member 100 is positioned on the lower surface and chamfer portion of the side molding 90, such a problem may be not generated.

Also, although the grounding member 100 positioned in the gap G may be recognized as a seam that may be formed between the display modules 30A to 30P, recognition of the seam may be minimized by light absorption of the side molding 90 because the grounding member 100 is positioned below the side molding 90 in the first direction X.

A method of manufacturing the display module 30 according to an embodiment of the disclosure will be described in detail.

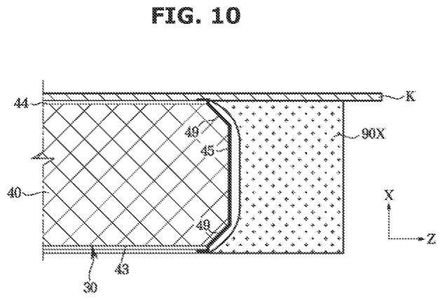

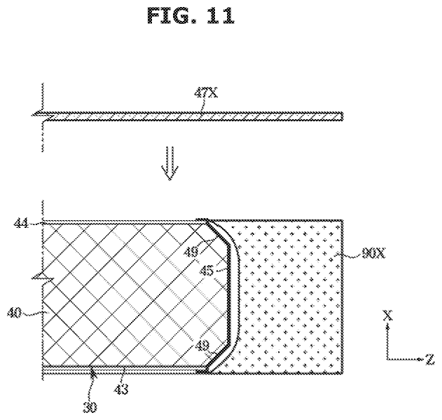

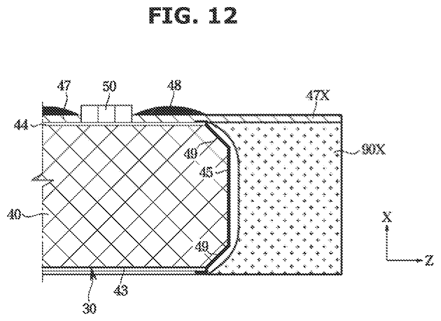

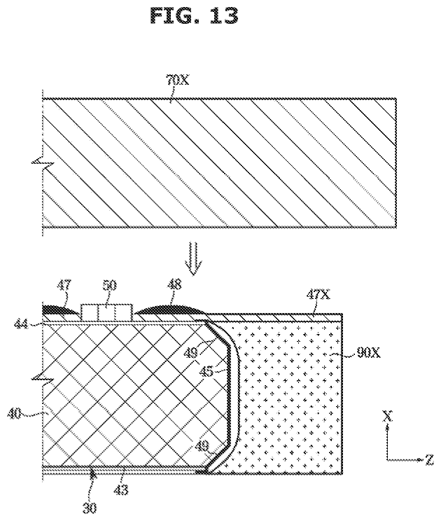

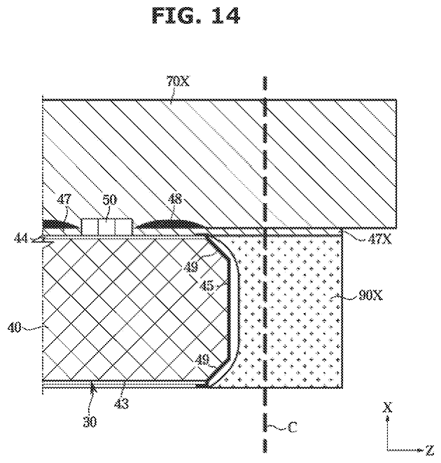

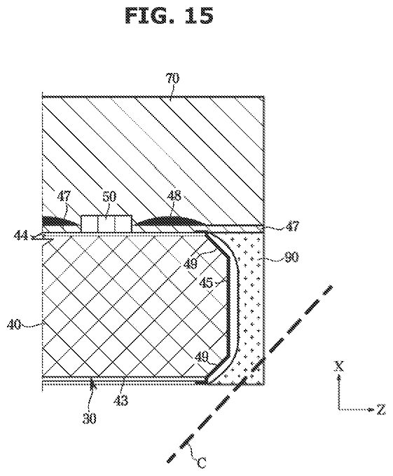

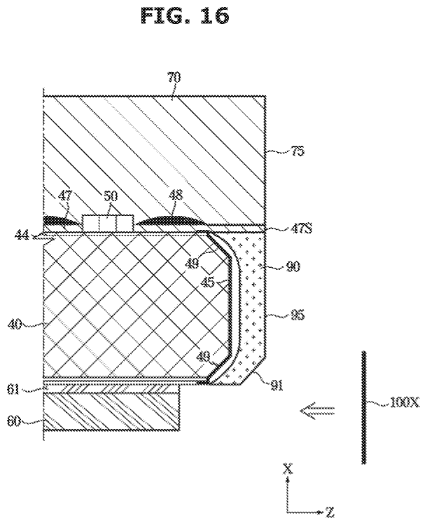

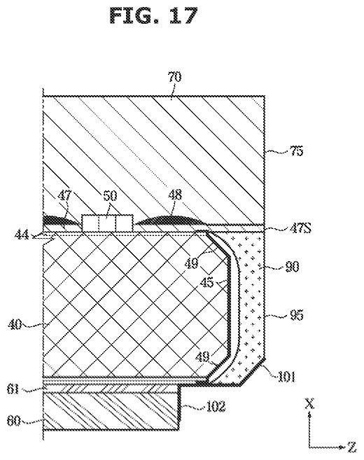

FIG. 10 shows a process of manufacturing a display device according to an embodiment of the disclosure, FIG. 11 shows a process of manufacturing the display device after FIG. 10, FIG. 12 shows a process of manufacturing the display device after FIG. 11 according to the disclosure, FIG. 13 shows a process of manufacturing the display device after FIG. 12, FIG. 14 shows a process of manufacturing the display device after FIG. 13 according to the disclosure, FIG. 15 shows a process of manufacturing the display device after FIG. 14 according to the disclosure, FIG. 16 shows a process of manufacturing the display device after FIG. 15 according to the disclosure, and FIG. 17 shows a process of manufacturing the display device after FIG. 16 according to the disclosure.

First, as shown in FIG. 10, a side molding 90X may be injected onto the substrate 40 in which the TFT layer 44, the rear wiring layer 43b, the side wire 46, etc. are formed on the mounting surface 41.

For example, the side molding 90X may be insert-injected through a mold.

A protecting film K may be adhered to the mounting surface 41 of the substrate 40 and a front end of the side molding 90X. The protecting film K may prevent the mounting surface 41 and wires, etc. formed on the mounting surface 41 from being damaged, while the substrate 40 is transferred.

The side molding 90X may be injected onto four side surfaces 45 formed along the four edges of the mounting surface 41 to surround all the side surfaces 45. Because the side wire 46 is positioned on the side surface 45 in the third direction Z, the side molding 90X may surround all the side surfaces 45 and the side wire 46.

The side molding 90X may be molded to extend from a front end of the TFT layer 44 to the rear wiring layer 43b and a rear end of the insulating layer 43c covering the rear wiring layer 43b in the first direction X.

The side molding 90X may be in an injected state before being cut.

Thereafter, as shown in FIG. 11, the protecting film K may be removed, and an anisotropic conductive film 47X may be adhered at a location at which the protecting film K has been adhered.

The metal cover 100 may be bent to cover the rear surface 43, at least one portion of the side surface 45, and at least one portion of the side wire 46. Because the metal cover 100 covers the substrate 40, the substrate 40 may be prevented from being damaged by external forces during the sequential processes.

The anisotropic conductive film 47X may be adhered onto the TFT layer 44 of the substrate 40 covered with the metal cover 100.

The anisotropic conductive film 47X may extend to a more outer location than the side wire 46 in the third direction Z, with respect to the side surface 45 in the third direction Z.

The anisotropic conductive film 47X may be formed in a shape of a film such that an area of the anisotropic conductive layer 47 is larger than an area of the substrate 40. Accordingly, after the anisotropic conductive layer 47 is adhered to the TFT layer 44, a process of cutting the anisotropic conductive layer 47 such that the area of the anisotropic conductive layer 47 corresponds to the area of the substrate 40 may be performed. The cutting process may be CNC cutting, etc., and in the sequential processes, a front cover 70X and a side member 90X may be cut together, although not limited thereto. However, the anisotropic conductive film 47X may be cut before the front cover 70X and the side member 90X are cut.

The anisotropic conductive film 47X may be in a state before being cut to be the anisotropic conductive layer 47.

Thereafter, as shown in FIG. 12, the plurality of inorganic light-emitting devices 50 may be mounted on the mounting surface 41. The plurality of inorganic light-emitting devices 50 may be electrically connected to wires of the substrate 40 by the anisotropic conductive film 47X. In addition, the black matrix 48 may be printed, and electronic components may be mounted on the mounting surface 41.

Thereafter, as shown in FIG. 13, the front cover 70X may be adhered on the mounting surface 41 of the display module 30 on which the plurality of inorganic light-emitting devices 50 and the electronic components configuring the display module 30 are mounted.

By positioning the front cover 70X on the anisotropic conductive film 47X, the front cover 70X may be adhered to cover the mounting surface 41. The front cover 70X may be in a state before being cut. The front cover 70X may cover an entire area of the mounting surface 41.

The front cover 70X may be adhered on the mounting surface 41 through a compression hardening process on the mounting surface 41.

Then, as shown in FIG. 14, the front cover 70X, the anisotropic conductive film 47X, and the side molding 90X may be cut in the first direction X such that at least one portion of the front cover 70X extends to a more outer location than the substrate 40 in the second and third directions Y and Z that are orthogonal to the first direction X which the mounting surface 41 faces.

The cutting process may be performed by CNC cutting, etc. through a CNC machine. The cutting process may limit damage to components to be cut, compared to existing laser cutting, and may be formed by a wet method to prevent burr that may occur in the anisotropic conductive film 47X, etc.

Accordingly, the front cover 70X, the side molding 90X, and the anisotropic conductive film 47X may be cut simultaneously, and the side ends 75, 47S and 95 thereof may be aligned in the first direction X.

Thereafter, as shown in FIG. 15, the side molding 90 may be additionally cut to form the chamfer portion 91 between the side end 95 and the lower surface of the side molding 90. At this time, the cutting process may be performed through CNC cutting, etc. as described above.

Then, as shown in FIG. 16, the metal plate 60 may be adhered to the rear surface 43 of the substrate 40.

The rear adhesive tape 61 may be positioned on an upper surface of the metal plate 60 in the first direction X to adhere the metal plate 60 to the substrate 40 while the rear adhesive tape 61 is compressed to the rear surface 43 of the substrate 40, although not limited thereto.

However, the rear adhesive tape 61 may be positioned on the rear surface 43 of the substrate 40, and then, the metal plate 60 may be compressed to the rear adhesive tape 61 positioned on the rear surface 43.

Then, a grounding member 100X may be positioned on the chamfer portion 91 and lower surface of the side molding 90 and the side surface of the metal plate 60.

The grounding member 100X may be adhered to the side molding 90 and the metal plate 60 by an adhesive layer, although not shown in the drawings. The grounding member 100X may be in a shape of a quadrangular sheet before being bent.

Then, as shown in FIG. 17, the grounding member 100 may be bent such that the first end 101 of the grounding member 100 is positioned on the chamfer portion 91 of the side molding 90, and the second end 102 is in contact with the metal plate 60.

A display device according to an embodiment of the disclosure may have a seamless effect in which seams are not visible by absorbing light entering gaps between neighboring display modules.

A display device according to an embodiment of the disclosure may secure reliability against Electrostatic Discharge (ESD) of a substrate of each display module and rigidity against external forces of the substrate because a side molding covering side surfaces of the substrate seals the side surfaces of the substrate by injection.

The above-described embodiments are merely specific examples to describe technical content according to the embodiments of the disclosure and help the understanding of the embodiments of the disclosure, not intended to limit the scope of the embodiments of the disclosure. Accordingly, the scope of various embodiments of the disclosure should be interpreted as encompassing all modifications or variations derived based on the technical spirit of various embodiments of the disclosure in addition to the embodiments disclosed herein.

What is claimed is:

1. A display module comprising:
a substrate comprising a mounting surface on which a plurality of inorganic light-emitting devices are mounted, a side surface, and a rear surface opposite to the mounting surface;
a front cover covering the mounting surface and extending to an outer area from the mounting surface;
a metal plate positioned on the rear surface of the substrate;
a side molding covering the side surface and positioned below the outer area from the mounting surface; and
a grounding member grounded to the metal plate and adhered to a lower surface of the side molding,
wherein the side molding is injection-molded on the side surface of the substrate and is in contact with the side surface.

2. The display module of claim 1, wherein a side end of the front cover positioned in the outer area from the mounting surface, and a side end of the side molding are aligned in a direction which the mounting surface faces.

3. The display module of claim 1, further comprising a Thin Film Transistor (TFT) layer formed on the mounting surface, and an anisotropic conductive layer positioned on an upper surface of the TFT layer and configured to electrically connect the TFT layer to the plurality of inorganic light-emitting devices,
wherein the anisotropic conductive layer extends to the outer area from the mounting surface.

4. The display module of claim 3, wherein a side end of the front cover positioned in the outer area from the mounting surface, and a side end of the anisotropic conductive layer positioned in the outer area from the mounting surface are aligned in a direction which the mounting surface faces.

5. The display module of claim 4, wherein the side end of the front cover, the side end of the anisotropic conductive layer, and a side end of the side molding are aligned in the direction which the mounting surface faces.

6. The display module of claim 1, wherein the side molding comprises a chamfer portion positioned between the lower surface of the side molding and a side end of the side molding, and
wherein the grounding member extends from the metal plate and is in contact with the lower surface of the side molding and the chamfer portion of the side molding.

7. The display module of claim 6, wherein the grounding member is positioned at a more inner location than the side end of the side molding in a direction that is orthogonal to a direction which the mounting surface faces.

8. A display device comprising a display module array in which a plurality of display modules are arranged horizontally in a matrix form of M*N, wherein each of the plurality of display modules comprises:
a substrate comprising a mounting surface on which a plurality of inorganic light-emitting devices are mounted, a side surface, and a rear surface opposite to the mounting surface;
a front cover covering the mounting surface and extending to an outer area from the mounting surface;
a metal plate mounted on the rear surface of the substrate;
a side molding covering the side surface and positioned below the outer area from the mounting surface; and
a grounding member being grounded to the metal plate and adhered to a lower surface of the side molding,
wherein the side molding is injection-molded on the side surface of the substrate and is in contact with the side surface.

9. The display device of claim 8, wherein a side end of the front cover positioned in the outer area from the mounting surface, and a side end of the side molding are aligned in a direction which the mounting surface faces.

10. The display device of claim 9, further comprising a thin film transistor (TFT) layer formed on the mounting surface, and an anisotropic conductive layer positioned on an upper surface of the TFT layer and configured to electrically connect the TFT layer to the plurality of inorganic light-emitting devices,
wherein the anisotropic conductive layer extends to the outer area from the mounting surface.

11. The display device of claim 10, wherein the side end of the front cover positioned in the outer area from the mounting surface, and a side end of the anisotropic conductive layer positioned in the outer area from the mounting surface are aligned in the direction which the mounting surface faces.

12. The display device of claim 8, wherein the side molding comprises a chamfer portion positioned between the lower surface of the side molding and a side end of the side molding, and
wherein the grounding member extends from the metal plate and is in contact with the lower surface of the side molding and the chamfer portion of the side molding.

13. The display device of claim 12, wherein the grounding member is positioned at a more inner location than the side end of the side molding in a direction that is orthogonal to the direction which the mounting surface faces.

14. A method of manufacturing a display module, comprising:
providing a substrate including a mounting surface on which a Thin Film Transistor (TFT) layer is formed, a side surface, and a rear surface being opposite to the mounting surface, wherein a wire is formed on the substrate;
injection-molding a side molding on the side surface of the substrate;
adhering an anisotropic conductive film onto the TFT layer;
mounting a plurality of inorganic light-emitting devices on the mounting surface;
adhering a front cover onto the mounting surface, the front cover extending to an outer area from the mounting surface; and
cutting the front cover, the anisotropic conductive film, and the side molding simultaneously in a direction which the mounting surface faces.

15. The method of claim 14, further comprising providing a metal plate in contact with the rear surface of the substrate.
